(19) United States
(12) Patent Application Publication
(10) Pub. No.: US 2005/0224712 A1
(43) Pub. Date: Oct. 13, 2005

(54) Device and method for eye problems

(76) Inventor: Thomas W. Wing, Claremont, CA (US)

Correspondence Address: Kit M. Stetina, Esq.;STETINA BRUNDA GARRED & BRUCKER, Suite 250, 75 Enterprise, Aliso Viejo, CA, 92656, US

(21) Appl. No.: 10/819,823

(22) Filed: Apr. 7, 2004

(51) Int. Cl. H01L 31/00

(52) U.S. Cl. 250/330

(57) ABSTRACT

A device for improving vision of a person, having a camera and a display. The camera has an image sensor operative to capture an image of a predetermined area in front of the person, and an image processor operative to compress the image. The display is operative to reproduce the compressed image. Preferably, the image sensor is effective to detect infrared light, and an infrared illuminator is incorporated to radiate an infrared light upon the predetermined area. Therefore, even in the dim-lit condition, the predetermined area can be properly imaged. However, as the infrared image is barely visible to human eyes, a wavelength shifter is used to translate the compressed image with infrared wavelength to visible wavelength before the compressed image is displayed by the display.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

The present invention relates in general to a device and a method for vision improvement, and more particularly, to a device and a method which improve night vision and peripheral vision of a driver who has vision deficiencies such as retinitis pigmentosa (RP).

There are two types of photoreceptors in the retina, including rod cells and cone cells. The cone cells are concentrated in the macula (center of the retina) to perceive color and fine visual detail at the center of vision. The rod cells are present both within and outside the macula and are responsible for night vision, seeing in dim light and side or peripheral vision. As the peripheral retina is predominated with rod cells, the peripheral retina is thus responsible for side vision and vision in low light conditions. When the rod cells start degenerating, a decrease in night vision and the inability to see dimly lit places such as movie theaters take places. The progressive loss of peripheral sight leads to what is called tunnel vision. Such gradual reduction in the ability to see peripherally may cause numerous physical problems such as tripping over objects or a motor vehicle accidents.

Thus, there exists a substantial need to develop a device and a method to improve peripheral vision and night vision, such that a person suffering from weak peripheral and night vision such as retinitis pigmentosa can drive a car with reduced risk of causing a road accident.

### BRIEF SUMMARY OF THE INVENTION

The present invention provides a device for improving vision of a person, comprising a camera and a display. The camera includes an image sensor operative to capture an image of a predetermined area in front of the person, and an image processor operative to compress the image. The display is operative to reproduce the compressed image. Preferably, the image sensor is effective to detect infrared light, and an infrared illuminator is incorporated to radiate an infrared light upon the predetermined area. Therefore, even in the dim-lit condition, the predetermined area can be properly pictured. However, as the infrared image is barely visible to human eyes, a wavelength shifter is used to translate the compressed image with infrared wavelength to visible wavelength before the compressed image is displayed by the display. The wavelength shifter is built in the processor or the display, for example. In addition to infrared image, the image sensor is also effective to detect visible light.

To obtain a wide angle view, the camera further comprises a wide angle lens for focusing incident light onto the image sensor. In one embodiment, the image processor includes an electronic or optical convex mirror or lens. Preferably, the display includes a flat panel display such as a liquid crystal display or an electroluminescence display. Therefore, by installing a lenticular, a three-dimensional effect can be provided by the display.

When the vision improvement device is applied to a vehicle, the display is mounted above or built into the dashboard of the vehicle, and the camera is mounted to the vehicle at a position having an unobstructed view of the roadway and without obstructing the view of the driver. The infrared illuminator is also mounted to the vehicle for projecting infrared radiation on the predetermined area.

The present invention further provides a method of improving vision of a person. An image of a predetermined area in front of the person is captured, preferably, by an image capturing device sensitive to both infrared and visible light. The image of the predetermined area is compressed and then reproduced by a display. Preferably, the method further comprises a step of radiating the predetermined area with infrared light, such that under dim-lit condition, the predetermined area can be precisely pictured. Consequently, the processed image may contain an infrared portion which is barely visible to human eyes. The method thus further comprises a step of converting the processed image in infrared light range into an image in visible light range.

In one alternate embodiment, a device for improving peripheral and dim-lit vision of a driver of a vehicle is provided. The device comprises a pair of cameras mounted to the vehicle at two sides in front of the driver and a pair of flat-panel displays mounted above or built in a dashboard of the vehicle. Each of the cameras comprises an image capturing device operative to capture images located on the left or right portion of a predetermined area in front of the driver and a processor and are operative to compress the image captured by the image capturing device. Each of the flat-panel displays is operative to reproduce the compressed image of the respective camera. The device may further comprise an infrared illuminator mounted to the vehicle at a position operative to radiate infrared light to the predetermined area.

The device described above can be converted into a portable version which comprises a frame configured to be worn by a user, a liquid crystal display fitted in the frame, an infrared illuminator mounted to the frame, and a micro-camera mounted to the frame. The infrared illuminator is operative to illuminate an infrared light on a predetermined area in front of the user. The micro-camera is operative to capture an image of the predetermined area and compress the image. The device further comprises a wavelength shifter to convert the processed image with infrared wavelength to an image with visible wavelength. A lenticular may be incorporated adjacent to the liquid crystal display to provide three-dimensional visual effect.

### BRIEF DESCRIPTION OF THE DRAWINGS

These as well as other features of the present invention will become more apparent upon reference to the drawings therein:

FIG. 1 shows a perspective view of a vision improvement device of the present invention applied to a vehicle;

FIG. 2 is a block diagram showing the components of the vision improvement device;

FIG. 3 is a flow chart showing a method of improving peripheral and night vision;

FIG. 4 is a perspective view of a modification of the vision improvement device as shown in FIG. 1; and

FIG. 5 shows a portable version of a vision improvement device.

### DETAILED DESCRIPTION OF THE INVENTION

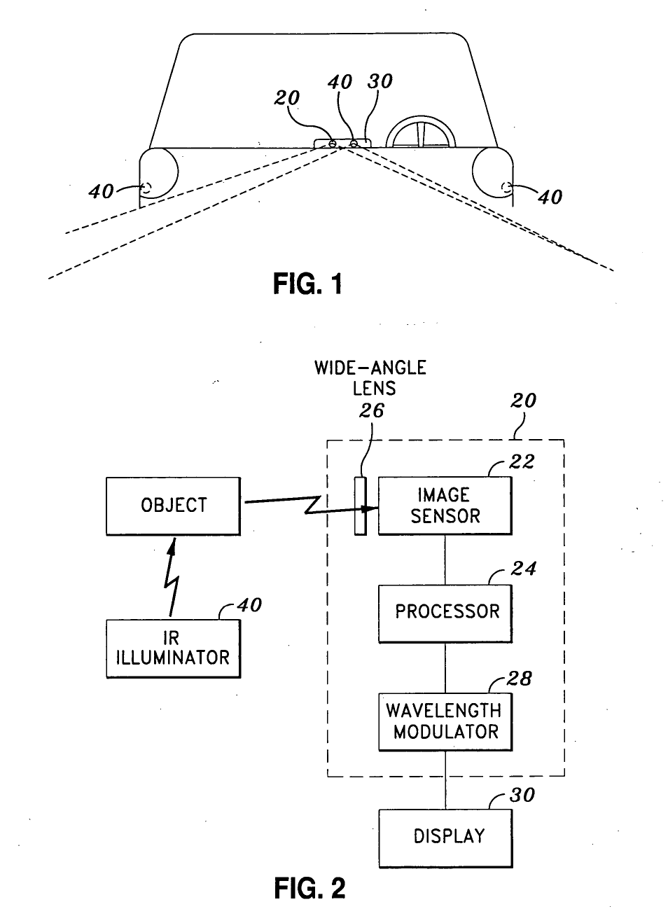

Referring now to the drawings wherein the showings are for purpose of illustrating preferred embodiments of the present invention only, and not for purposes of limiting the same. As shown in FIGS. 1 and 2, the present invention provides a vision improvement device which incorporates a camera 20 and a display 30 in electric communication with each other. The camera 20 is preferably installed in a vehicle 10 at a position operative to capture a wide angle of view in front of the driver without obstructing the view of the driver. To obtain a wide angle and unobstructed of view, the camera 20 may also be mounted to the vehicle 10 externally. The display 30 is either installed above or built in the dashboard 12 of the vehicle 10, such that the driver can glance at the display 30 without being distracted by moving his or her head.

The camera 20 includes an image capturing device 22 for scanning a predetermined area and capturing an image of the predetermined area in front of the driver of the vehicle 10. The image capturing device 22 is either a conventional analog sensor or detector, or a digital sensor such as charged-coupled device (CCD) or complementary metal-oxide semiconductor (CMOS) image sensor, for example. Preferably, the effective sensing angle of the image capturing device 22 is no less than about 180°, and a wide angle lens 26 is preferably incorporated to obtain such wide viewing angle.

As mentioned above, the driver having retinitis pigmentosa has very weak dim-light vision. Therefore, when the visibility is low such as under the conditions of rain, snow, fog or darkness, the ambient light and illumination provided by the vehicle 10 are too poor to provide proper visibility for the driver. The present invention further provides an infrared illuminator 40 which projects an infrared light on a predetermined area in front of the driver. The infrared light is barely visible to human eyes, such that projection of the infrared light will not encounter road risk by affecting the visibility of other drivers or pedestrians on the road. The infrared illuminator 40 can be installed in proximity of the camera 20, such that the camera 20 basically covers the whole effective illuminating range of the infrared illuminator 40. Alternatively, the infrared illuminator 40 can also be built in any of the existing front lamp such as head light, indicating light or side light. In such case, more than one infrared illuminator 40 can be used. As the predetermined area in front of the driver is radiated by infrared illumination, the camera 20 with an effective sensing wavelength range extending from visible light to infrared light, that is, from about 0.4 micron to about 15 microns, is operative to capture an image of the predetermined area illuminated by both infrared light and dim visible light. Therefore, under the twilight, fog, rain and snow conditions, objects in the predetermined area in front of the driver can be precisely pictured and reproduced.

When the image capturing device 22 scans the predetermined area in front of the driver, an image of the predetermined area is captured and output to a processor 24. The image output to the processor 24 is either in the form of an optical signal, or is modulated in an electronic form by the image capturing device 22. As mentioned above, as the retinitis pigmentosa affects the peripheral vision and dim-lit vision of the driver, the processor 24 is designed to increase the brightness of the image and compress the image. In one embodiment, the processor 24 is in the form of an electronic or optical convex lens or mirror that converges the image and concentrates the brightness of the image onto the focal point thereof. As the peripheral area of the image is concentrated, the intensity of the processed image is increased. It will be appreciated that artificial brightening effect may also be applied to the image by the processor, such that the overall intensity of the image can be increased.

The image processed by the processor 24 is then output to the display 30. Preferably, the display 30 includes a flat panel display such as an electroluminescence (EL) display or a liquid crystal display (LCD). The display 30 is operative to reproduce the image captured by the image capturing device 22 with increased intensity and a converging effect. As the image captured by the image capturing device 22 covers the visible and infrared ranges of light, the processor 24 is also operative to shift the infrared wavelength of the image into the visible range. Alternatively, the display 30 may incorporate a wavelength modulator, such that the infrared image can be translated into visual image as displayed. Further, a person having retinitis pigmentosa often has difficulty in judging distance of an image from a two-dimensional screen. Therefore, a display with three-dimensional visual effect can be used to further help the driver to determine the distance of a displayed image correctly. As known in the art, the conventional display such as a cathode ray tube (CRT) screen has severe optical problems in achieving three-dimensional visual effect. However, with the flat-panel display, a lenticular can be incorporated to provide a three-dimensional visual effect which does not require the viewer to wear special three-dimensional viewing glasses.

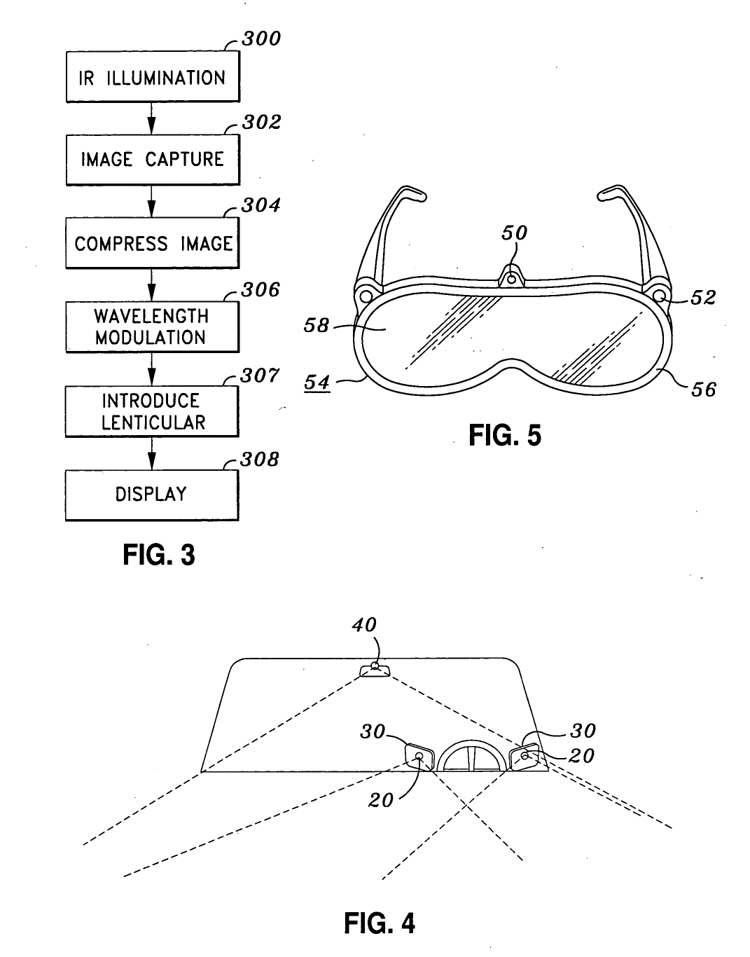

FIG. 3 illustrates a method of improving peripheral and night vision of a person, particularly a person having retinitis pigmentosa. As shown, to improve the dim lit visibility without adversely effecting other drivers or pedestrians on the road with extra brightness of visible light, an infrared light is illuminating upon a predetermined area in step 300. Thereby, objects in the predetermined area are not only radiated by existing visible light, but are also radiated by the infrared light. In step 302, an image of the predetermined area in front of the person is captured. Preferably, the camera 20 with the wide angle lens 26 is used to scan and capture image in both visible range and infrared range of light. Therefore, even when the road condition is poor, such as dark, rainy, snowy, or foggy, the predetermined area in front of the person can be clearly imaged. In step 304, the captured image is compressed and brightened. As mentioned above, preferably, the captured image is compressed and the brightness of the captured image is increased. In step 306, as the captured image may cover light from the visible light range to infrared light range, the portion of the infrared range is shifted to the visible light range before being displayed. In step 308, the compressed and shifted light is displayed. Preferably, a flat panel display is used for displaying the compressed image, such that by introducing a lenticular in the display in step 307, a three-dimensional effect is imposed on the image. Therefore, the person is not only able to obtain the peripheral and night visions, but is also able to determine the distance of each object contained in the image.

In one alternate embodiment, a pair of cameras 20 and a pair of displays 30 can be used for providing better stereoscopic effect. FIG. 4 illustrates the vision improvement device with improved stereoscopic effect. As shown, instead of a single camera 20, two cameras 20 are mounted to the vehicle 10. The cameras 20 are located on opposite sides in front of the driver. In this way, a wider viewing range is obtained, and a wide angle lens becomes optional because a single wide angle lens often distorts the edge of the image captured thereby. The image captured by the cameras 20 are output to respective displays 30 for display. The displays 30 are preferably located above or in the dashboard at both sides of the driver. Preferably, orientations of the displays 30 can be adjusted in accordance to individual driver preference. Again, to improve dim-light vision, at least one infrared illuminator 40 may also be incorporated.

The vision improvement devices as illustrated in FIGS. 1 and 3 to 4 are suitably applied to a vehicle to help the driver obtaining the peripheral vision and night vision. Such design can also be modified into a portable version such that a person in all locations can be assisted in enhancing peripheral and dim lit visions. FIG. 5 exemplarily shows a portable version of the vision improvement device provided by the present invention. As shown, the device includes a mini infrared light illuminator 50 and a micro-camera 52 fitted to a goggle 54 that comprises a frame 56 and a flat panel display 58 fitted within the frame 56. The function of the infrared illuminators 50 and the micro-camera 52 are similar to the infrared illuminator 40 and the camera 20 as discussed above. The flat panel display 58 includes a liquid crystal layer powered by an individual mini battery or the camera 52 that includes a built-in power source. The flat panel display 58 receives an image captured and processed by the camera 52 and reproduces the image. Preferably, a lenticular is attached to the liquid crystal layer to provide three-dimensional visual effect.

While an illustrative and presently preferred embodiment of the invention has been described in detail herein, it is to be understood that the inventive concepts may be otherwise variously embodied and employed and that the appended claims are intended to be construed to include such variations except insofar as limited by the prior art.

1. A device for improving vision of a person, comprising:
a camera, including:
an image sensor operative to capture an image of a predetermined area in front of the person; and
an image processor operative to compress the image; and
a display operative to reproduce the compressed image.

2. The device of claim 1, wherein the image sensor is effective to detect infrared light.

3. The device of claim 2, further comprising an infrared illuminator operative to radiate an infrared light upon the predetermined area.

4. The device of claim 1 or 2, further comprising a wavelength shifter to translate the compressed image with infrared wavelength to visible wavelength.

5. The device of claim 4, wherein the wavelength shifter is built in the processor or the display.

6. The device of claim 2, wherein the image sensor is effective to detect visible light.

7. The device of claim 1, wherein the image sensor is effective to detect both visible light and infrared light.

8. The device of claim 1, wherein the camera further comprises a wide angle lens for focusing incident light onto the image sensor.

9. The device of claim 1, wherein the image processor includes an electronic or optical convex mirror or lens.

10. The device of claim 1, wherein the display includes a flat panel display.

11. The device of claim 10, wherein the flat-panel display includes a liquid crystal display or an electroluminescence display.

12. The device of claim 1, wherein the display is mounted above or built in a dashboard of a vehicle driven by the person, and the camera is mounted to the vehicle at a position having an unobstructed view and without obstructing view of the person.

13. The device of claim 12, further comprising an infrared illuminator mounted to the vehicle for projecting infrared radiation on the predetermined area.

14. The device of claim 1, wherein the display includes a three-dimensional flat panel display.

15. The device of claim 15, wherein the display comprises a displaying layer and a lenticular.

16. A method of improving vision of a person, comprising the step of:
a) detecting an image of a predetermined area in front of the person;
b) compressing the image of the predetermined area; and
c) reproducing the compressed image by a display.

17. The method of claim 16, further comprising a step of radiating the predetermined area with infrared light before step (a).

18. The method of claim 17, further comprising a step of shifting the processed image in infrared light range into visible light range before step (c).

19. A device for improving peripheral and dim-lit vision of a driver in a vehicle, comprising:
a pair of cameras mounted to the vehicle at two sides in front of the driver, wherein each of the cameras comprises:
an image capturing device, operative to capture images left or right portion of a predetermined area in front of the driver; and
a processor, operative to compress the image captured by the image capturing device; and
a pair of flat-panel displays mounted above or built in a dashboard of the vehicle, wherein each of the flat-panel displays is operative to reproduce the compressed image of the respective camera.

20. The device of claim 19, further comprising an infrared illuminator mounted to the vehicle at a position operative to radiate infrared light to the predetermined area.

21. A portable vision improvement device, comprising:
a frame configured to be worn by a user;
a liquid crystal display fitted in the frame;
an infrared illuminator mounted to the frame; and
a micro-camera mounted to the frame.

22. The device of claim 21, wherein the infrared illuminator is operative to illuminate an infrared light on a predetermined area in front of the user.

23. The device of claim 22, wherein the micro-camera is operative to capture an image of the predetermined area.

24. The device of claim 23, wherein the micro-camera is operative to compress the image.

25. The device of claim 24, further comprising a wavelength shifter to convert the processed image with infrared wavelength to an image with visible wavelength.

26. The device of claim 1, further comprising a lenticular adjacent to the liquid crystal display to provide three-dimensional visual effect.
